(19) United States
(12) Patent Application Publication
(10) Pub. No.: US 2009/0296858 A1
(43) Pub. Date: Dec. 3, 2009

(54) DEM SYSTEM, DELTA-SIGMA A/D CONVERTER, AND RECEIVER

(76) Inventors: Mai NOZAWA, Kawasaki-Shi (JP); Takeshi UENO, Kawasaki-Shi (JP); Masanori FURUTA, Mishima-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/205,384

(22) Filed: Sep. 5, 2008

(30) Foreign Application Priority Data
May 28, 2008 (JP) 2008-139639

(51) Int. Cl. H04L 27/22; H03M 1/12; H03M 7/00

(52) U.S. Cl. 375/332; 341/155; 341/63

(57) ABSTRACT

A DEM (dynamic element matching) system in which a digital signal is inputted, has a switching circuit which, being equipped with a plurality of switches, each of the plurality of switches is subjected to on/off control based on a switch control signal, receives a first thermometer code in which the total number of logic ones and logic zeros corresponding to the digital signal is “n” and outputs a second thermometer code in which the total number of logic ones and logic zeros is “n” (where “n” is an integer equal to or larger than 2), a latch circuit which latches the second thermometer code output from the switching circuit and outputs the second thermometer code, and a switch control signal generating circuit which generates the switch control signal using the digital signal or the second thermometer code output from the latch circuit and outputs the switch control signal.

### CROSS REFERENCE TO RELATED APPLICATION

This application is based upon and claims the benefit of priority from the prior Japanese Patent Application No. 2008-139639, filed on May 28, 2008, the entire contents of which are incorporated herein by reference.

### BACKGROUND OF THE INVENTION

The present invention relates to a DEM system, a delta-sigma A/D converter, and a receiver.

A delta-sigma A/D converter integrates (Σ) differences (Δ) between analog inputs and digital outputs using a loop filter, the digital outputs having been converted into analog values by an internal D/A converter, converts the value of integral into a digital value using an internal A/D converter, and outputs the digital value after latching by a latch circuit. The latch circuit is used to adjust inputs into the internal D/A converter.

The delta-sigma A/D converter has a feature that its stability decreases with increases in a loop delay. It is known that the stability can be ensured when latency between output from the internal A/D converter and input into the internal D/A converter is equal to or smaller than a ½ clock pulse.

Also, the use of a multi-bit architecture for the internal D/A converter allows the delta-sigma A/D converter to reduce an oversampling ratio to achieve necessary performance, thereby improving the stability.

Overall performance of the delta-sigma A/D converter is limited by accuracy of the internal D/A converter, and thus it is necessary to improve the accuracy of the internal D/A converter. Generally D/A converters are affected directly by device accuracy, and methods have been worked out to improve device accuracy. The methods include a dynamic element matching (hereinafter referred to as DEM) method which suppresses the effect of device accuracy by uniformly using all cells in the D/A converter.

However, if a DEM circuit is installed between the latch circuit and internal D/A converter of a delta-sigma A/D converter such as described above, since the DEM circuit starts calculation after an output signal is provided from the latch circuit, the latency between output from the internal A/D converter and input into the internal D/A converter exceeds a ½ clock pulse, decreasing the stability of the entire delta-sigma A/D converter.

To solve this problem, a technique has been proposed which uses a flash A/D converter made up of “n” comparators as an internal A/D converter (where “n” is an integer equal to or larger than 2), installs a switch group between the A/D converter and a reference voltage generating circuit which generates “n” reference voltages, controls connections of the switch group based on output from a latch circuit and information on D/A conversion cells used in the previous cycle, and scrambles input into the A/D converter (see, for example, U.S. Pat. No. 7,227,491).

However, the technique is applicable only to a circuit in which there is a correspondence between reference voltages and inputs into the A/D converter as in the case of a flash A/D converter. Also, since variations in the reference voltages will cause performance degradation of the A/D converter (quantizer) and entire delta-sigma A/D converter, the reference voltage generating circuit requires high buffering capacity.

### SUMMARY OF THE INVENTION

According to one aspect of the present invention, there is provided a DEM (dynamic element matching) system in which a digital signal is inputted, comprising:

a switching circuit which, being equipped with a plurality of switches, each of the plurality of switches is subjected to on/off control based on a switch control signal, receives a first thermometer code in which the total number of logic ones and logic zeros corresponding to the digital signal is “n” and outputs a second thermometer code in which the total number of logic ones and logic zeros is “n” (where “n” is an integer equal to or larger than 2);

a latch circuit which latches the second thermometer code output from the switching circuit and outputs the second thermometer code; and

a switch control signal generating circuit which generates the switch control signal using the digital signal or the second thermometer code output from the latch circuit and outputs the switch control signal.

According to one aspect of the present invention, there is provided a delta-sigma A/D converter comprising a DEM system, the DEM system including a switching circuit which, being equipped with a plurality of switches, each of the plurality of switches is subjected to on/off control based on a switch control signal, receives a first thermometer code in which the total number of logic ones and logic zeros corresponding to a digital signal is “n” and outputs a second thermometer code in which the total number of logic ones and logic zeros is “n” (where “n” is an integer equal to or larger than 2), a latch circuit which latches the second thermometer code output from the switching circuit and outputs the second thermometer code, and a switch control signal generating circuit which generates the switch control signal using the digital signal or the second thermometer code output from the latch circuit and outputs the switch control signal.

According to one aspect of the present invention, there is provided a receiver, comprising:

an antenna which receives a signal;

an amplifier which amplifies the signal received by the antenna and outputs a first analog signal;

a local oscillator which outputs a first local signal;

a 90-degree phase shifter which receives the first local signal and outputs a second local signal and a third local signal 90 degrees out of phase with each other;

a first frequency converter which converts frequency of the first analog signal using the second local signal and outputs a second analog signal;

a second frequency converter which converts frequency of the first analog signal using the third local signal and outputs a third analog signal;

a first A/D converter which converts the second analog signal into a first digital signal and a second A/D converter which converts the third analog signal into a second digital signal, where each of the first A/D converter and the second A/D converter is a delta-sigma A/D converter which has a DEM system, the DEM system including a switching circuit which, being equipped with a plurality of switches, each of the plurality of switches is subjected to on/off control based on a switch control signal, receives a first thermometer code in which the total number of logic ones and logic zeros corresponding to a digital signal is “n” and outputs a second thermometer code in which the total number of logic ones and logic zeros is “n” (where “n” is an integer equal to or larger than 2), a latch circuit which latches the second thermometer code output from the switching circuit and outputs the second thermometer code, and a switch control signal generating circuit which generates the switch control signal using the digital signal or the second thermometer code output from the latch circuit and outputs the switch control signal; and

a digital signal processing unit which decodes the first digital signal and the second digital signal.

### BRIEF DESCRIPTION OF THE DRAWINGS

FIG. 1 is a schematic block diagram of a delta-sigma A/D converter according to an embodiment of the present invention;

FIG. 2 is a schematic block diagram of a D/A converting unit in the delta-sigma A/D converter according to the embodiment;

FIG. 3 is a diagram showing an example of a switching circuit and the D/A converting unit in the delta-sigma A/D converter according to the embodiment;

FIG. 4 is a table showing an exemplary operation of a DEM system according to the embodiment;

FIG. 5 is a timing chart showing an example of input and output to/from the DEM system according to the embodiment;

FIG. 6 is a schematic block diagram of a switch control signal generating circuit in the DEM system according to the embodiment;

FIG. 7 is a schematic block diagram of a remainder computing unit in the switch control signal generating circuit according to the embodiment;

FIG. 8 is a table showing an example of correspondence between input and output to/from a selector in the switch control signal generating circuit according to the embodiment;

FIG. 9 is a schematic block diagram of the DEM system according to the embodiment;

FIGS. 10(a) and 10(b) are schematic block diagrams of DEM systems according to variations; and

FIG. 11 is a schematic block diagram of a wireless receiver obtained by application of the delta-sigma A/D converter according to the embodiment.

### DESCRIPTION OF THE EMBODIMENTS

An embodiment of the present invention will be described below with reference to the drawings.

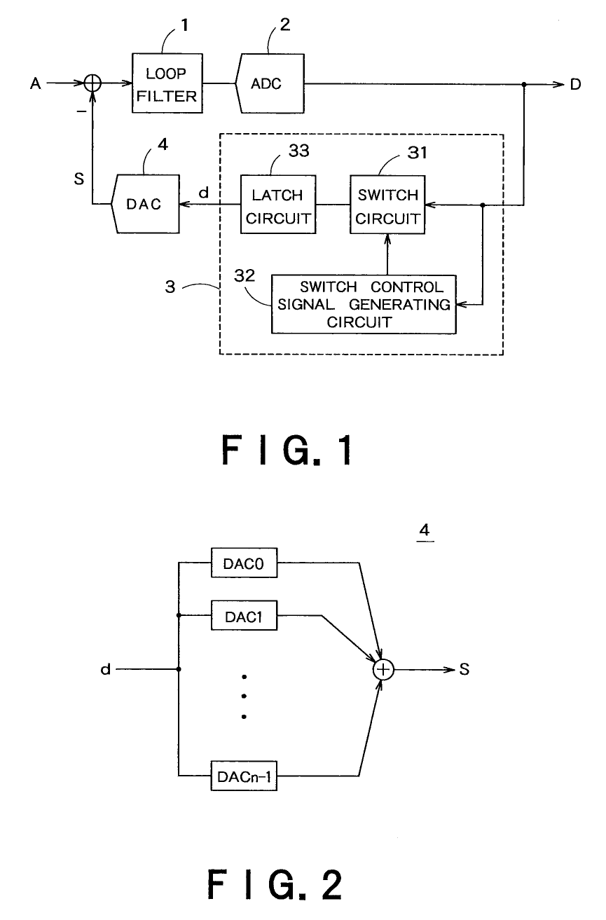

FIG. 1 shows a schematic configuration of a delta-sigma A/D converter according to an embodiment of the present invention. The delta-sigma A/D converter is a multi-bit delta-sigma A/D converter which includes a loop filter 1, an A/D converting unit 2, a DEM unit 3, and a D/A converting unit 4 as well as a feedback control loop. The delta-sigma A/D converter is designed such that latency (waiting time) between output from the A/D converting unit 2 and input into the D/A converting unit 4 will be equal to or smaller than a ½ clock pulse.

The loop filter 1 receives a difference between an analog input signal A and an output signal S from the D/A converting unit 4. The A/D converting unit 2 receives an output signal from the loop filter 1, performs analog-digital conversion, and outputs a digital signal D.

The A/D converting unit (quantizing unit) 2 has “n” quantization thresholds (where “n” is an integer equal to or larger than 2). The output digital signal D is a thermometer code in which the total number of logic zeros and logic ones is “n”. The digital signal D is inputted in the DEM unit 3. An output digital signal d of the DEM unit 3 is converted into an analog signal S by the D/A converting unit 4. When the control loop is in steady state, the output signal S of the D/A converting unit 4 coincides with the analog input signal A.

As shown in FIG. 2, the D/A converting unit 4 has “n” unweighted unit D/A conversion cells DAC0 to DACn−1 and generates the signal S by adding outputs of the unit D/A conversion cells DAC0 to DACn−1. For example, the “n” unit D/A conversion cells DAC0 to DACn−1 have equivalently weighted current sources.

The DEM unit 3 which is a DEM system according to the present embodiment includes a switching circuit 31, a switch control signal generating circuit 32, and a latch circuit 33. The switching circuit 31 and the switch control signal generating circuit 32 receive, as input, the thermometer code which is the output D from the A/D converting unit 2.

The switch control signal generating circuit 32 generates a switch control signal in the current cycle based on the output from the A/D converting unit 2 and a switch control signal output in the previous cycle. The switching circuit 31 has its inputs and outputs (inputs to the latch circuit 33) connected in a one-to-one relationship and the connection is switched based on the switch control signal. The outputs from the switching circuit 31 are latched by the latch circuit 33 and inputted in the D/A converting unit 4.

Input and output signals of the switching circuit 31 and input and output signals of the latch circuit 33 correspond to the output from the A/D converting unit 2 and input into the D/A converting unit 4. The total number of logic ones and logic zeros in both input and output is “n”.

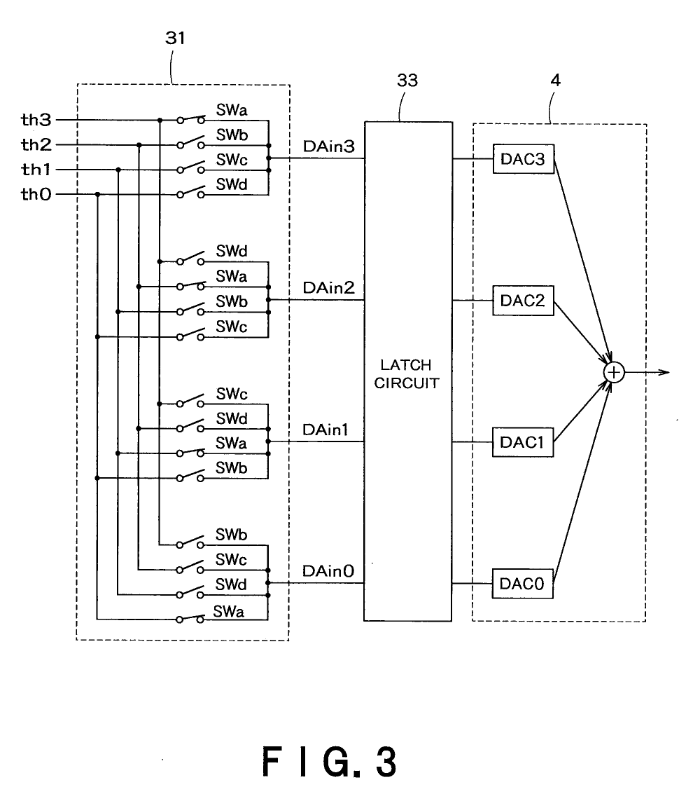

Operation of the DEM unit 3 will be described taking as an example a case in which n=4. As shown in FIG. 3, an input signal of the switching circuit 31 (output signal from the A/D converting unit 2) includes thermometer codes th0 to th3. Input signals of the latch circuit 33 (output signals from the switching circuit 31) are DAin0 to DAin3, which correspond to input signals of the “n” unit D/A conversion cells DAC0 to DAC3 of the D/A converting unit 4.

The switching circuit 31 has switches SWa to SWd between the inputs th0 to th3 and each of the outputs DAin0 to DAin3. The switches SWa to SWd are subjected to on/off control such that one of the switches SWa to SWd will be on with the other switches remaining off in each clock cycle, based on the switch control signal output from the switch control signal generating circuit 32.

For example, when the switch SWa is on and the switches SWb to SWd are off, the thermometer codes th0, th1, th2, and th3 are output as DAin0, DAin1, DAin2, and DAin3, respectively.

On the other hand, when the switch SWd is on and the switches SWa to SWc are off, the thermometer codes th1, th2, th3, and th0 are output as DAin0, DAin1, DAin2, and DAin3, respectively.

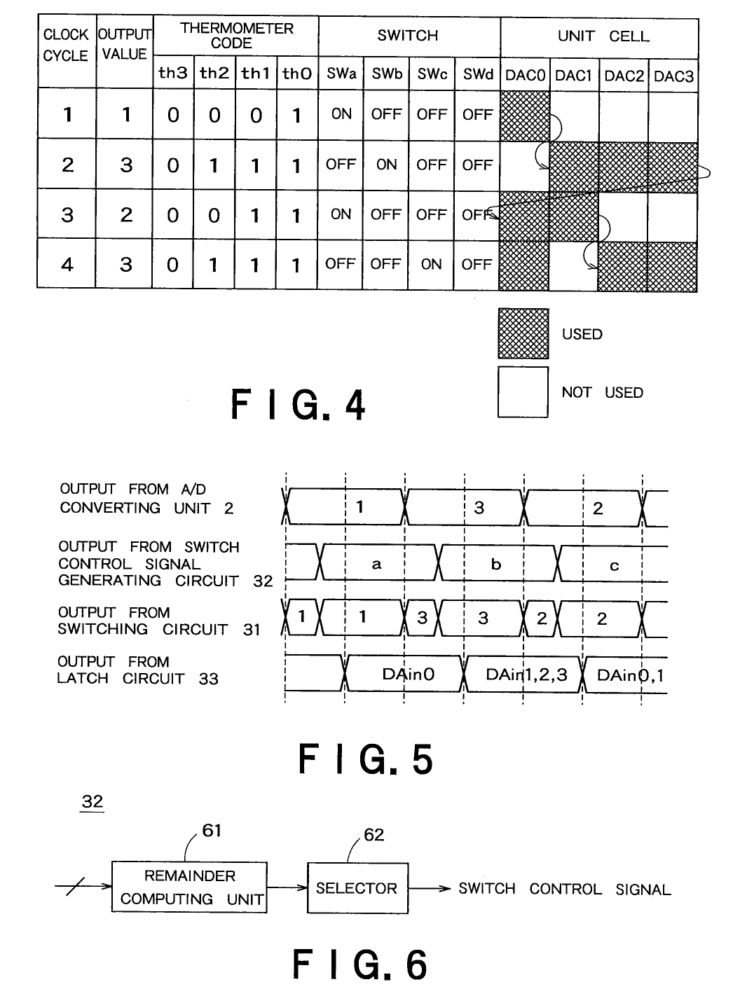

FIG. 4 shows an example of an output value of the A/D converting unit 2, thermometer codes, switch status, and the unit D/A conversion cells used, in each clock cycle. In cycle 1, the output value of the A/D converting unit 2 is “1”, and the thermometer code th0 is “1” and the thermometer codes the to th3 are “0”. At this time, if a switch control signal which turns on the switch SWa is generated, the unit D/A conversion cell DAC0 is used.

In cycle 2, the output value of the A/D converting unit 2 is “3”, and the thermometer codes th0 to th2 are “1” and the thermometer code th3 is “0”. Since the unit D/A conversion cell DAC0 was used in the previous cycle (cycle 1), the switch control signal generating circuit 32 generates a switch control signal which turns on the switch SWb so that unit D/A conversion cells will be used beginning with DAC1. Consequently, the unit D/A conversion cells DAC1 to DAC3 are used in the D/A converting unit 4.

In cycle 3, the output value of the A/D converting unit 2 is “2”, and the thermometer codes th0 and the are “1” and the thermometer codes th2 and th3 are “0”. Since the unit D/A conversion cells DAC1 to DAC3 were used in the previous cycle (cycle 2), the switch control signal generating circuit 32 generates a switch control signal which turns on the switch SWa so that unit D/A conversion cells will be used beginning with DAC0. Consequently, the unit D/A conversion cells DAC1 and DAC2 are used in the D/A converting unit 4.

In cycle 4, the output value of the A/D converting unit 2 is “3”, and the thermometer codes th0 to th2 are “1” and the thermometer code th3 is “0”. Since the unit D/A conversion cells DAC1 and DAC2 were used in the previous cycle (cycle 3), the switch control signal generating circuit 32 generates a switch control signal which turns on the switch SWc so that unit D/A conversion cells will be used beginning with DAC3. Consequently, the unit D/A conversion cells DAC0, DAC2, and DAC3 are used in the D/A converting unit 4.

As operations such as described above are repeated, usage counts of the unit D/A conversion cells are averaged. Consequently, an average value of output errors due to mismatches of unit D/A conversion cells is reduced and a power spectrum is shaped into a high-pass type.

FIG. 5 shows a timing chart of the output from the A/D converting unit 2, output from the switch control signal generating circuit 32, output from the switching circuit 31, and output from the latch circuit 33 (input to the D/A converting unit 4) in the example shown in FIG. 4. The output from the switching circuit 31 is switched at the times when the output from the A/D converting unit 2 is switched and when the output from the switch control signal generating circuit 32 is switched.

The switch control signal generating circuit 32 is not installed on a path from the output of the A/D converting unit 2 to the input of the D/A converting unit 4 (A/D converting unit 2->switching circuit 31->latch circuit 33->D/A converting unit 4). Consequently, the time required by the switch control signal generating circuit 32 to generate a switch control signal does not affect the latency from the output of the A/D converting unit 2 to the input of the D/A converting unit 4. That is, the use of the DEM unit 3 according to the present embodiment does not increase the latency.

A schematic configuration of the switch control signal generating circuit 32 is shown in FIG. 6. The switch control signal generating circuit 32 includes a remainder computing unit 61 and a selector 62. The remainder computing unit 61 adds the current output value of the A/D converting unit 2 and an output value of the remainder computing unit 61 in the previous cycle, divides the sum by “N+1” (where “N” is a positive integer, which is a maximum output value of the A/D converting unit 2), and thereby calculates and outputs the remainder.

The selector 62 generates the switch control signal for on/off control of the switches in the switching circuit 31 based on the remainder output from the remainder computing unit 61.

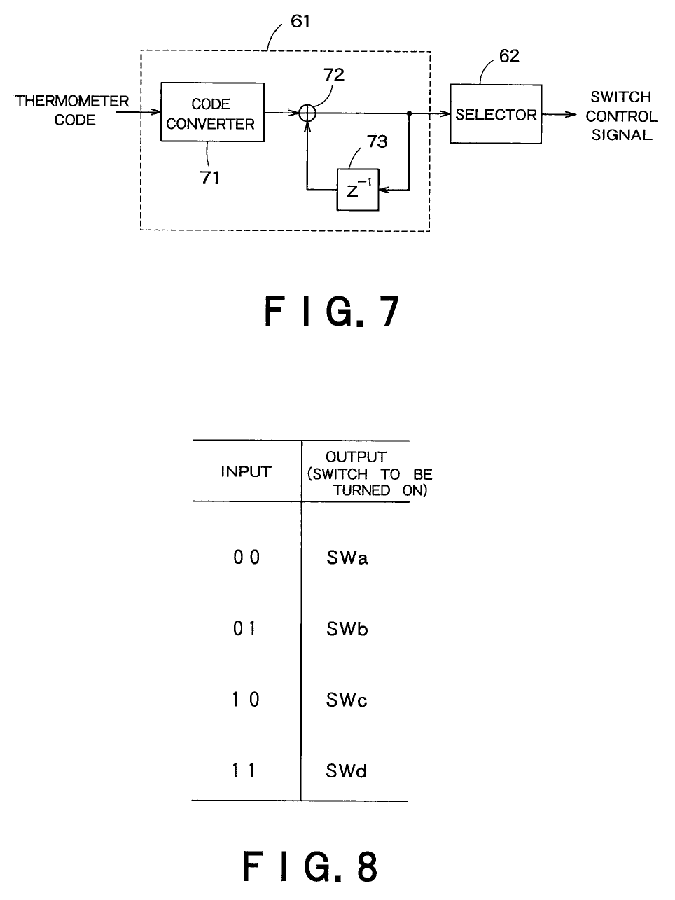

A configuration example of the remainder computing unit 61 is shown in FIG. 7. The remainder computing unit 61 includes a code converter 71, an m-bit adder 72, and a delay device 73, where “m” is an integer which satisfies 2^{m}=N+1. The code converter 71 converts thermometer codes into m-bit binary codes. The adder 72 adds output of the code converter 71 and output of the delay device 73 (output of the adder 72 in the previous cycle) and outputs the sum to the selector 62. With the m-bit adder 72, since information higher than the m-th bit of the addition result is truncated, the remainder left after a division by “N+1” can be determined.

FIG. 8 shows a relationship between input and output to/from the selector 62 shown in the example of FIGS. 3 and 4. Two-bit (2-bit) binary codes are inputted in the selector 62. Codes “00”, “01”, “10”, and “11” are assigned to the switches SWa to SWd and the selector 62 outputs a switch control signal to turn on one of the switches according to the code.

In cycle 1, the switch SWa is turned on. When the binary code “01” (thermometer code “0001”) is inputted, the adder 72 adds the inputted signal “01” and the output of the adder in the previous cycle (“00” in this case because there is no previous cycle). Consequently, the adder 72 outputs “01”, and the selector 62 outputs a signal which turns on the switch SWb corresponding to “01” in cycle 2.

In cycle 2, when the binary code “11” (thermometer code “0111”) is inputted, the output “01” of the adder 72 in cycle 1 is added to the binary code “11”, and “00” is inputted in the selector 62. Thus, the selector 62 outputs a signal which turns on the switch SWa corresponding to “00” in cycle 3.

In cycle 3, when the binary code “10” (thermometer code “0011”) is inputted, the output “00” of the adder 72 in cycle 2 is added to the binary code “10”, and “10” is inputted in the selector 62. Thus, the selector 62 outputs a signal which turns on the switch SWc corresponding to “10” in cycle 4.

As the above cycles are repeated, usage counts of the unit D/A conversion cells are averaged.

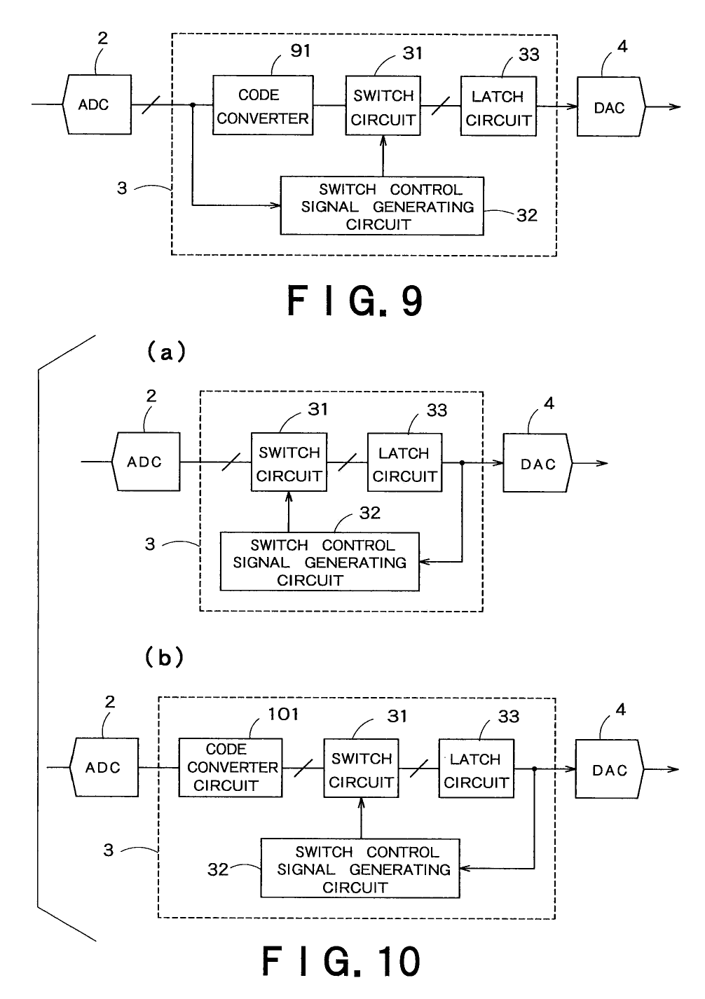

If the output signal of the A/D converting unit 2 contains binary codes instead of thermometer codes, a code converter 91 is installed between the A/D converting unit 2 and the switching circuit 31 to convert the binary codes into thermometer codes as shown in FIG. 9. Then, the output of the A/D converting unit 2 is inputted in the switch control signal generating circuit 32 (remainder computing unit 61).

The output of the A/D converting unit 2 according to the present embodiment may be in any form as long as there is a circuit which converts the signal into thermometer codes before input into the switching circuit 31. Since the outputs of the A/D converting unit 2 do not need to correspond one-to-one with the inputs of the D/A converting unit 4, it is possible to use an A/D converting circuit other than a flash type (e.g., a subranging A/D converting circuit such as described in the document of A. G. F. Dingwall, “An 8-MHz CMOS Subranging 8-bit A/D Converter” IEEE J. Solid-State Circuits, Vol. SC-20, No. 6, pp. 1138-1143, December 1985”) for the A/D converting unit 2 as well as to reduce a circuit scale. Besides, high buffering capacity is not required for reference voltage generated in the A/D converting unit 2.

Also, the switch control signal generating circuit 32 of the DEM unit 3 can control switching of the switches in the switching circuit 31 without increasing the latency from the output of the A/D converting unit 2 to the input of the D/A converting unit 4. This makes it possible to improve accuracy of the D/A converting unit 4.

In this way, the delta-sigma A/D converter according to the present embodiment has great versatility as well as improved accuracy and stability.

In the above embodiment, the switch control signal generating circuit 32 generates the switch control signal using the output signal of the A/D converting unit 2 as shown in FIG. 2, but all that needs to be known is those unit D/A conversion cells of the D/A converting unit 4 which were used in the previous cycle. Thus, as shown in FIG. 10(a), the switch control signal may be generated using the output of the latch circuit 33 (input of the D/A converting unit 4). Also, when the output of the A/D converting unit 2 is a binary code, a code converting circuit 101 is installed as shown in FIG. 10(b).

In the above embodiment, the switch control signal generating circuit 32 performs first order arithmetic operations as shown in FIG. 7, but the switch control signal generating circuit 32 may perform second or higher order arithmetic operations to further reduce noise around DC. For example, the switch control signal generating circuit 32 may be made up of multi-stage integrators and selectors.

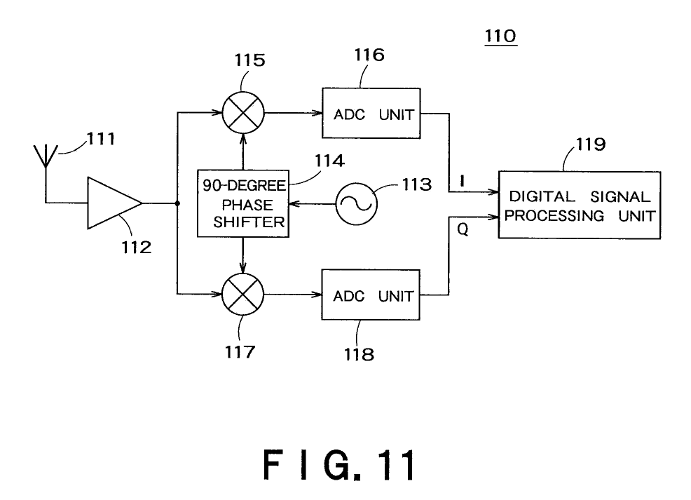

The delta-sigma A/D converter according to the above embodiment can be used as A/D converting units 116 and 118 in a wireless receiver 110 as shown in FIG. 11. A signal received via an antenna 111 is inputted in an LNA (Low Noise Amplifier) 112. The LNA 112 amplifies the received signal to a predetermined level and inputs the signal into frequency converting units 115 and 117.

A local oscillator 113 generates a local signal needed to convert the received signal into a baseband signal. A 90-degree phase shifter 114 splits the local signal into two parts and inputs one of the two parts into the frequency converting unit 115, and the other part into the frequency converting unit 117 by causing the second part to lag the first part by a phase difference of 90 degrees. The frequency converting units 115 and 117 multiply the received signal by the respective parts of the local signal, thereby generate analog baseband signals, and pass the analog baseband signals to the A/D converting units 116 and 118, respectively.

The A/D converting units 116 and 118 convert the respective analog baseband signals into digital baseband signals and input the digital baseband signals into a digital signal processing unit 119. The digital signal processing unit 119 decodes the inputted digital baseband signals.

Since the delta-sigma A/D converter according to the above embodiment are used as the A/D converting units 116 and 118, A/D conversion can be performed with a sufficient resolution even when input signal amplitude is small. This makes it possible to improve accuracy and stability.

What is claimed is:

1. A DEM (dynamic element matching) system in which a digital signal is inputted, comprising:
a switching circuit which, being equipped with a plurality of switches, each of the plurality of switches is subjected to on/off control based on a switch control signal, receives a first thermometer code in which the total number of logic ones and logic zeros corresponding to the digital signal is “n” and outputs a second thermometer code in which the total number of logic ones and logic zeros is “n” (where “n” is an integer equal to or larger than 2);
a latch circuit which latches the second thermometer code output from the switching circuit and outputs the second thermometer code; and
a switch control signal generating circuit which generates the switch control signal using the digital signal or the second thermometer code output from the latch circuit and outputs the switch control signal.

2. The DEM system according to claim 1, wherein the plurality of switches includes “n” switches installed between an input terminal for each logic value of the first thermometer code and output terminals for the second thermometer code; and one of the “n” switches turns on based on the switch control signal.

3. The DEM system according to claim 2, wherein the switch control signal generating circuit generates the switch control signal in the (k+1)-th clock cycle based on a switch turned on in the k-th clock cycle and the number of logic ones in the first thermometer code or in the second thermometer code (where “k” is an integer equal to or larger than 1).

4. The DEM system according to claim 3, wherein the switch control signal generating circuit comprises:
a remainder computing unit which adds an output value in the k-th clock cycle and an input value in (k+1)-th clock cycle, divides the sum by “N+1”, and thereby calculates and outputs the remainder (where “N” is a maximum value of the digital signal); and
a selector which selects a switch to be turned on from among the “n” switches, based on the remainder output from the remainder computing unit, and generates the switch control signal.

5. The DEM system according to claim 4, wherein the remainder computing unit comprises:
a delay device; and
an m-bit adder which adds an output value of the delay device and the input value and outputs the sum to the selector and the delay device (where “m” is an integer which satisfies 2^{m}=N+1).

6. The DEM system according to claim 5, wherein the digital signal is a thermometer code, the DEM system further comprising a code converter which converts the digital signal into a binary code and outputs the binary code to the adder.

7. The DEM system according to claim 5, further comprising a code converter installed between the latch circuit and the adder to convert thermometer codes into binary codes.

8. The DEM system according to claim 1, wherein the digital signal is a binary code, the DEM system further comprising a code converter which converts the digital signal into a thermometer code and outputs the thermometer code as the first thermometer code to the switching circuit.

9. The DEM system according to claim 3, wherein the switch control signal generating circuit comprises:
a high-order integrator which receives the digital signal or the second thermometer code output from the latch circuit; and
a selector which selects a switch to be turned on from among the “n” switches, based on output from the integrator, and generates the switch control signal.

10. A delta-sigma A/D converter comprising the DEM system according to claim 1.

11. A receiver, comprising:
an antenna which receives a signal;
an amplifier which amplifies the signal received by the antenna and outputs a first analog signal;
a local oscillator which outputs a first local signal;
a 90-degree phase shifter which receives the first local signal and outputs a second local signal and a third local signal 90 degrees out of phase with each other;
a first frequency converter which converts frequency of the first analog signal using the second local signal and outputs a second analog signal;
a second frequency converter which converts frequency of the first analog signal using the third local signal and outputs a third analog signal;
a first A/D converter which converts the second analog signal into a first digital signal, the first A/D converter being the delta-sigma A/D converter according to claim 10;
a second A/D converter which converts the third analog signal into a second digital signal, the second A/D converter being the delta-sigma A/D converter according to claim 10; and
a digital signal processing unit which decodes the first digital signal and the second digital signal.
